(19) United States
(12) Patent Application Publication
(10) Pub. No.: US 2019/0122486 A1
(43) Pub. Date: Apr. 25, 2019

(54) DISPLAY DEVICE AND GAME MACHINE

(71) Applicant: OMRON Corporation, Kyoto (JP)

(72) Inventors: Taichi Onoyama, Aichi (JP); Hiroyuki Onitsuka, Gifu (JP); Takahiro Ono, Aichi (JP); Takehiro Agata, Aichi (JP)

(73) Assignee: OMRON Corporation, Kyoto (JP)

(21) Appl. No.: 16/138,557

(22) Filed: Sep. 21, 2018

(30) Foreign Application Priority Data
Oct. 20, 2017 (JP) 2017-204038

(51) Int. Cl. G07F 17/32; H01L 25/075; H01L 25/16; H01L 33/60; G07F 17/34; G09G 3/32

(52) U.S. Cl. CPC G07F 17/3213; H01L 25/0753; H01L 25/0756; G09G 3/32; H01L 33/60; G07F 17/34; H01L 25/167

(57) ABSTRACT

A display device includes a light emitting part having at least one transparent substrate on a front surface of which a plurality of light emitting devices (LEDs) are mounted, an LED control board configured to control light emission of the plurality of LEDs, a half mirror part disposed on a light launching side of the light emitting part and having a light reflection function and a light transmission function, and a mirror part disposed on a rear surface side of the light emitting part and having at least the light reflecting function out of the light reflecting function and the light transmission function.

### CROSS-REFERENCE TO RELATED APPLICATION

This application is based on Japanese Patent Application No. 2017-204038 filed with the Japan Patent Office on Oct. 20, 2017, the entire contents of which are incorporated herein by reference.

### FIELD

The present invention relates to a display device using an action of a combination mirror.

### BACKGROUND

There has been a display device that performs a light emission display using an action of a combination mirror (infinite mirror). For example, Japanese Unexamined Patent Application Publication No. 2014-233375 discloses a glass unit that is provided in a window part of a game machine and performs a light emission display using an action of a combination mirror.

This glass unit includes a frame, a front glass plate, a rear glass plate, and a flexible substrate on which a plurality of light-emitting diodes (LEDs) are mounted. The flexible substrate is attached to the inside of a frame sandwiched between the front glass plate and the rear glass plate, and the LEDs mounted on the flexible substrate are arranged with predetermined intervals on the inner peripheral surface of the frame. When the LEDs emit light, the player sees a plurality of points of light (virtual image) linearly continuing from the LEDs toward the rear (depth direction) of the rear side glass plate by action of the combination mirror formed of the front glass plate and the rear glass plate.

However, in the conventional configuration, due to the need for arranging the light emitting elements without hindering the action of the combination mirror, the LEDs are fixed to the frame. As a result, a symbol and movement represented by the light of the LED and its virtual image are limited to those conforming to the shape of the frame and lack the flexibility of expression.

### SUMMARY

The present invention has been made in view of the above conventional problems, and it is an object of the present invention to provide a display device and a game machine capable of achieving with high flexibility a light emission display having a sense of depth.

In order to solve the above problems, a display device according to a first aspect of the present invention includes: a light emitting part having at least one transparent substrate, on a front surface of which a plurality of light emitting elements are mounted; a light emission control board configured to control light emission of the plurality of light emitting elements; a first mirror part disposed on a light launching side of the light emitting part and having a light reflection function and a light transmission function; and a second mirror part disposed on a rear surface side of the light emitting part and having at least the light reflecting function out of the light reflecting function and the light transmission function.

With the above configuration, the light emitting part includes at least one transparent substrate on which a plurality of light emitting elements are mounted, and the first mirror part and the second mirror part are disposed on both sides of the transparent substrate. Since the first mirror part disposed on the light launching side has the light transmission function, a user can see a real image of light launched from the lit light emitting element and a virtual image of light launched from the lit light emitting element through the first mirror part. A part of the light emitted from the light emitting element is repeatedly reflected between the first mirror part and the second mirror part and proceeds. The user sees this light as the virtual image of the lit light emitting element continuing or intermittently continuing in a depth direction (rearward). As thus described, with the above configuration, it is possible to perform a light emission display with a sense of depth while maintaining the thinness of the display device by action of the combination mirror formed of the first mirror part and the second mirror part.

Moreover, with the above configuration, since the plurality of light emitting elements are mounted on the transparent substrate, the light emitting element can be mounted at a freely selected position without hindering the action of the combination mirror. Hence a light emission display of a freely selected symbol can be performed and a light emission display having a sense of depth can be achieved with a high degree of freedom.

A display device in a second aspect of the present invention is a configuration in which in the first aspect, the light emitting part includes a plurality of the transparent substrates, and the plurality of transparent substrates are laminated.

With the above configuration, by laminating the transparent substrates, the light emitting elements can be arranged at different positions in the depth direction (positions with different depths from the surface). Thus, for example, by switching over lighting and blinking of the light emitting elements, light movement in the depth direction can be expressed to achieve a light emission display more complicated and more impactful than a configuration having only one transparent substrate. Further, with the transparent substrate in use, even when a plurality of transparent substrates are laminated, the thinness of the display device is not hindered and the thin form can be maintained.

A display device in a third aspect of the present invention is a configuration in which in the second aspect, at least a part of the plurality of light emitting elements mounted on each of the plurality of transparent substrates overlaps in a plan view.

With the above configuration, since at least a part of the light emitting elements overlaps in a plan view among the plurality of transparent substrates, the real image of the lit light emitting element can be made to continue in the depth direction (rearward). Moreover, at that time, the virtual images of the lit light emitting elements which are visible by action of the combination mirror become images large in number and have high light intensity and luminance as compared to a virtual image formed by the single-layer light emitting elements. It is thus possible to achieve a more impactful light emission display.

A display device in a fourth aspect of the present invention is a configuration in which in the first to third aspects, the first mirror part and the second mirror part are disposed in a non-parallel state.

As a result, even when the display device is viewed from the front, a virtual image of light continuing toward the rear can be shown.

A display unit in a fifth aspect of the present invention is a configuration in which in the first to fourth aspects, the second mirror part has the light reflection function and the light transmission function, and the display device further includes an image display part that displays an image on the rear surface side of the second mirror part based on image data.

With the above configuration, since the second mirror part has the light transmission function and the display device further includes the image display part that displays an image on the rear surface side of the second mirror part based on image data, it is possible to perform a light emission display using the light emitting element by the light emitting part and an image display by the image display part.

This enables both a light emission display with a high luminance performance effect using the light emitting element by the light emitting part and an image display using the image display part, thereby providing a non-conventional novel display device.

A display device according to a sixth aspect of the present invention is a configuration in which in the fifth aspect, the display device further includes between the light emitting part and the image display part a light source part configured to increase light that passes through the second mirror part.

With the above configuration, since the light source part for increasing the light passing through the second mirror part is disposed between the light emitting part and the image display part, even when an image is over two mirrors (half mirrors) of the first mirror part and the second mirror part, the visibility of the image in the image display part can be made favorable.

A game machine in a seventh aspect of the present invention is characterized by including the display device according to the first to sixth aspects.

With the above configuration, the light emitting element is disposed at a freely selected position without hindering the action of the combination mirror, so that it is possible to provide a game machine provided with a display device capable of achieving the light emission display having the sense of depth, with a high degree of freedom.

According to one aspect, there is produced an effect of being able to provide a display device and a game machine capable of achieving with high flexibility a light emission display having a sense of depth.

### BRIEF DESCRIPTION OF THE DRAWINGS

FIGS. 1A-1C illustrate a display device and a game machine in one embodiment of the present invention, where FIG. 1A is a schematic perspective view of the display device and the game machine, FIG. 1B is a view illustrating an example of a light emission display in the display device, and FIG. 1C is a view illustrating an example of an image display in the display device;

FIG. 2 is an exploded perspective view of a display device according to a first embodiment;

FIG. 3 is a perspective view illustrating an appearance of the display device;

FIG. 4 is a rear view of a top panel included in the display device;

FIG. 5 is a plan view of a transparent substrate and an LED control substrate provided in the display device;

FIG. 6 is a plan view of a bottom base provided in the display device;

FIG. 7 is a vertical sectional view of a main part of the display device;

FIG. 8 is an explanatory view and a partially enlarged view illustrating a state in which the display device is performing a light emission display;

FIG. 9 is an exploded perspective view of a display device according to a second embodiment;

FIG. 10 is a transmission perspective view and a partially enlarged view of the display device according to the second embodiment;

FIG. 11 is a vertical sectional view of a main part of the display device according to the second embodiment;

FIG. 12 is an explanatory view and a partially enlarged view illustrating a state in which the display device according to the second embodiment is performing a light emission display;

FIG. 13 is an exploded perspective view of a display device according to a third embodiment;

FIG. 14 is a vertical sectional view of a main part of a display device according to a fourth embodiment; and

FIG. 15 is a block diagram of a main part of a display device according to a fifth embodiment.

### DETAILED DESCRIPTION

Hereinafter, an embodiment according to one aspect of the present invention (hereinafter also referred to as “the embodiment”) will be described with reference to the drawings. However, the embodiment described below is merely an example of the present invention in all respects. It goes without saying that various improvements and modifications can be made without departing from the scope of the present invention. In other words, in practicing the present invention, a specific configuration according to the embodiment may be adopted as appropriate.

### § 1 APPLICATION EXAMPLE

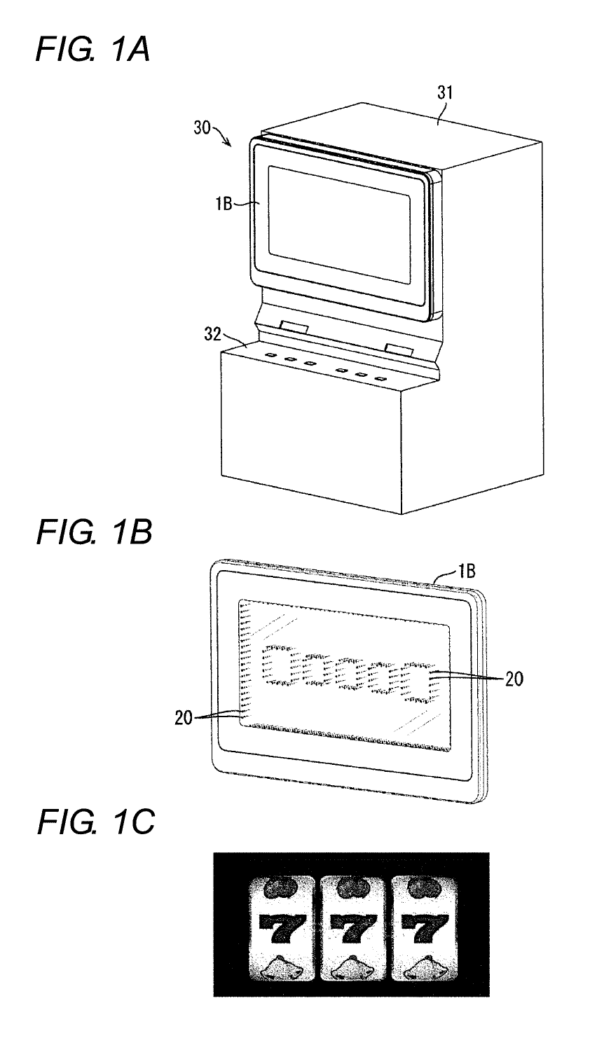

First, an example of a scene to which the present invention is applied will be described. FIGS. 1A-1C illustrate a display device 1B and a game machine 30 in one embodiment of the present invention, where FIG. 1A is a schematic perspective view of the display device 1B and the game machine 30, FIG. 1B is a view illustrating an example of a light emission display in the display device 1B, and FIG. 1C is a view illustrating an example of an image display in the display device 1B.

As illustrated in FIG. 1A, in the game machine 30, the display device 1B is provided on the front surface side of a casing 31, and an operation part 32 is provided below the display device 1B. Although not illustrated, the display device 1B includes a light emitting part provided with at least one transparent substrate on which a plurality of light emitting elements are mounted. As the light emitting element, for example, an LED can be used. Although not illustrated, a first mirror part having an optical function is disposed on the light launching side of the light emitting part, and a second mirror part is disposed on the rear surface side of the light emitting part. The display device 1B performs a light emission display with a sense of depth by light launched from an LED 20 as illustrated in FIG. 1B while maintaining the thinness of the display device by using the action of a combination mirror formed of the first mirror part and the second mirror part. By mounting the LED 20 on the transparent substrate, it is possible to dispose the LED 20 at a freely selected position without hindering the action of the combination mirror. In the example illustrated in FIG. 1B, the LEDs 20 are disposed at the outer edge and a central part of a display area.

In the display device 1B, the second mirror part has a light transmission function, and although not illustrated, the image display part is disposed on the rear surface side of the second mirror part. It is thereby possible to switch between the light emission display by the light emitting part as illustrated in FIG. 1B and the image display by the image display part as illustrated in FIG. 1C.

For example, when the game machine 30 is a slot machine and is in a normal state of performance, the display device 1B displays a reel image as illustrated in FIG. 1C. When the game machine 30 shifts from a normal performance to a special performance, the display device 1B starts performing a light emission display by using the LEDs 20 as illustrated in FIG. 1B. As compared to a performance by an image display device, a performance by the light emitting unit using the light emitting elements such as the LEDs 20 has high luminance, and hence an impactful performance can be conducted. Thus, the light emission display performed by the display device 1B is used also in the case of urging the player to play a game in a state where a game is not being played on the game machine 30 except for the special performance, or in some other case, so that the presence of the gaming machine can be strongly appealed to the player.

Although FIG. 1A exemplifies the slot machine as the game machine 30, the game machine 30 can be used for various game machines such as a pachinko machine, a pachinko-slot machine, and a gaming machine. The display device 1B can also be used for display devices such as industrial devices and consumer devices, and can also be applied to a display device of a personal computer, a smart phone, a tablet, an electronic bulletin board, and the like. In addition, the display devices 1 and 1A not provided with the image display unit described in the first and second embodiments can also be used for an illumination device of a game machine, an electric decoration device to be installed on a wall as a single body, and the like.

### § 2 CONFIGURATION EXAMPLE

### First Embodiment

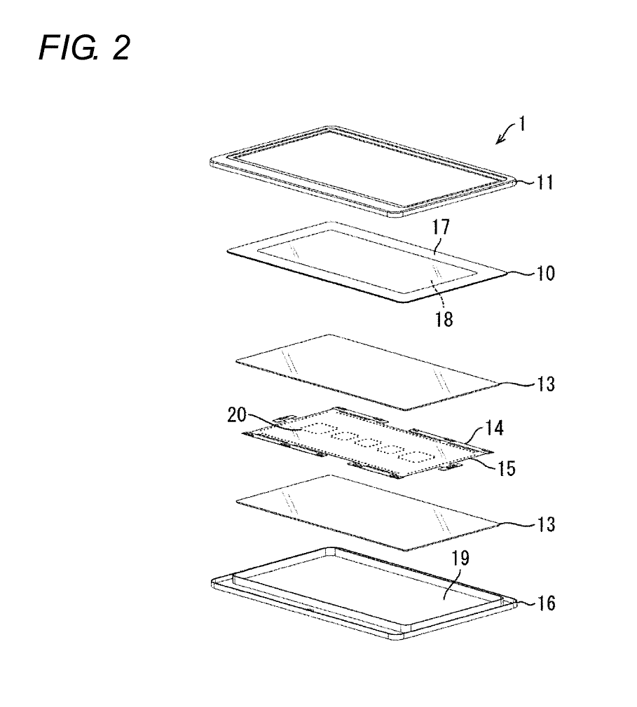

Hereinafter, an embodiment according to one aspect of the present invention will be exemplified with reference to FIGS. 2 to 8.

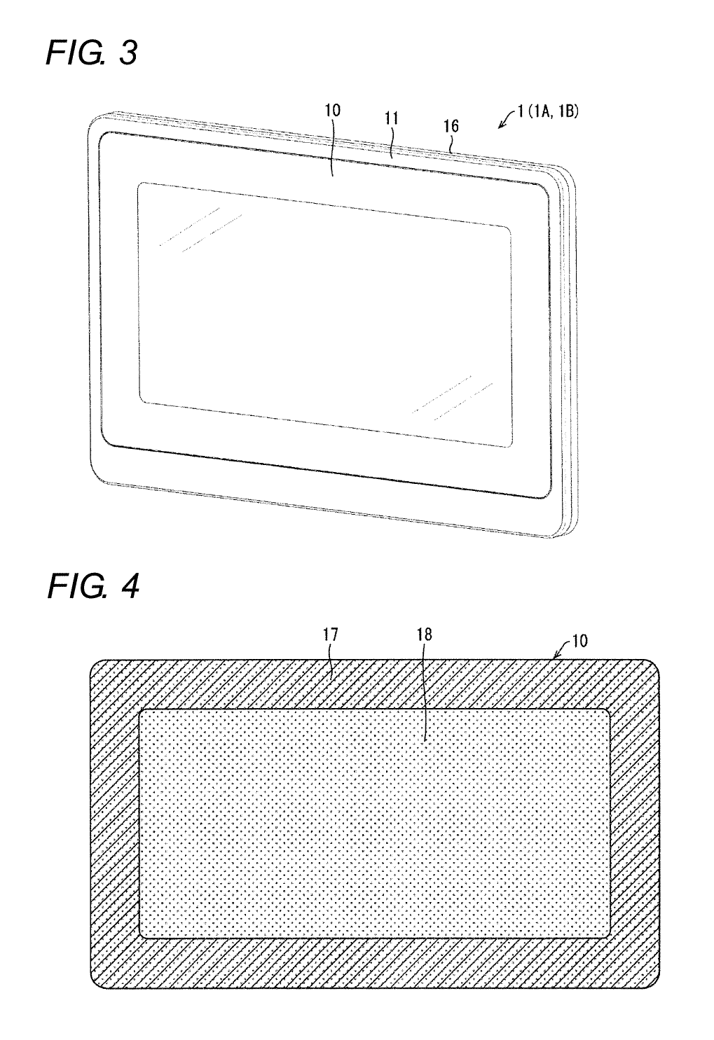

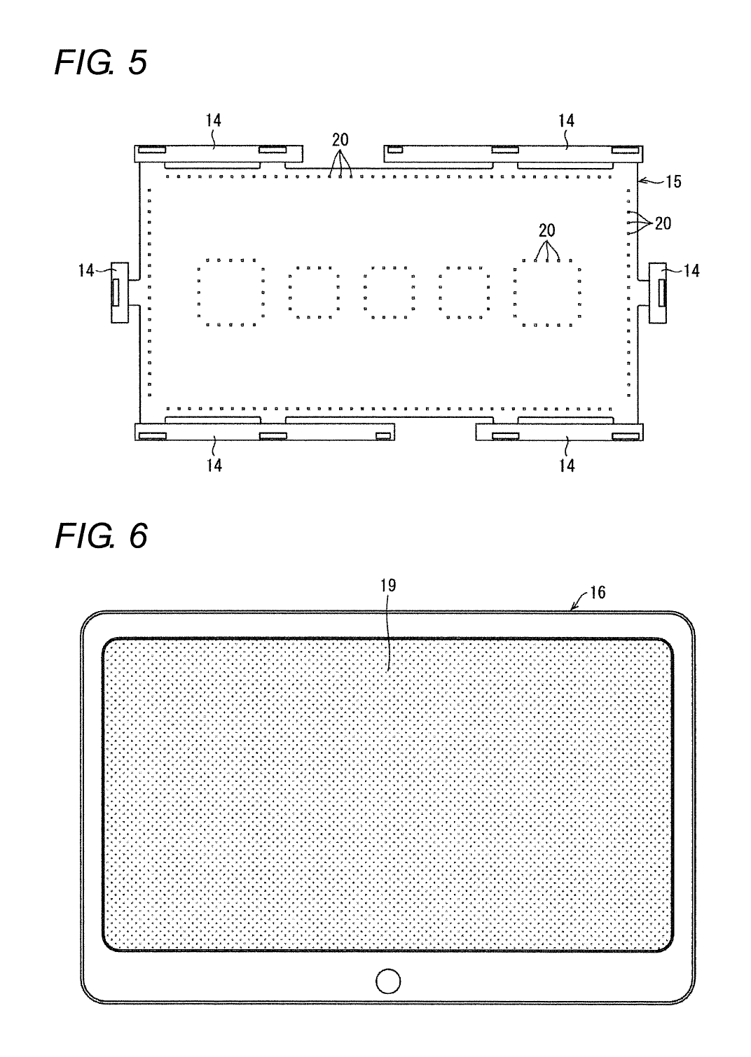

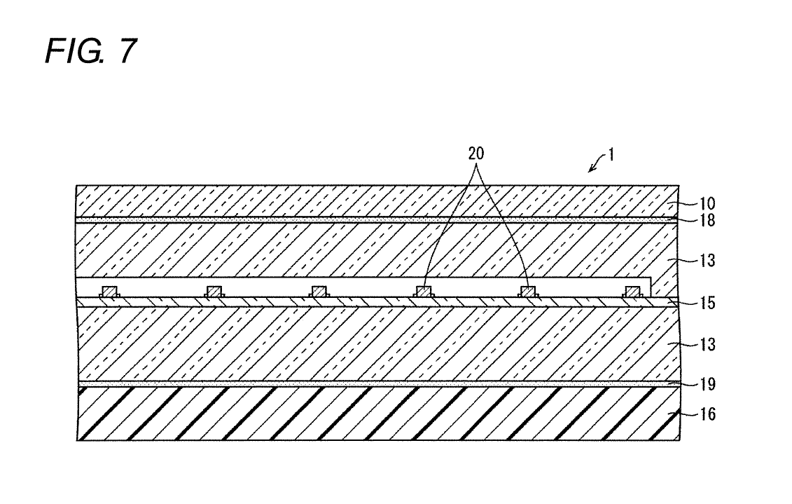

FIG. 2 is an exploded perspective view of a display device 1 according to the embodiment. FIG. 3 is a perspective view illustrating the external appearance of the display device 1. FIG. 4 is a rear view of a top panel 10 included in the display device 1. FIG. 5 is a plan view of a transparent substrate 15 and an LED control board 14 included in the display device 1. FIG. 6 is a plan view of a bottom base 16 of the display device 1. FIG. 7 is a vertical sectional view of a main part of the display device 1.

As exemplified in FIGS. 2 and 3, the display device 1 has, for example, a rectangular shape and includes the top panel 10, a frame part 11, two clear plates 13, a transparent substrate 15, an LED control board 14, a bottom base 16, and the like.

The top panel 10 is a transparent cover provided on the front surface (front-side surface) of the display device 1. The top panel 10 is made of a colorless transparent material such as polycarbonate, acrylic, or glass. As illustrated in FIG. 4, a black printed part 17 is formed on the peripheral edge of the rear surface (inner surface) of the top panel 10 by black printing (hatched part in FIG. 4). The black printed part 17 is for blindfolding the internal structure of the peripheral edge of the display device 1. Further, as illustrated in FIG. 4, a half mirror part 18 is formed on the entire rear surface (inner surface) of the top panel 10 by half mirror deposition (dotted part in FIG. 4). The half mirror part 18 has both functions of light reflection and light transmission, and constitutes one mirror part (first mirror part) of the combination mirror. The half mirror part 18 is also formed on the black printed part 17. Note that the half mirror part 18 may be formed by a method other than vapor deposition, such as attaching a half mirror film.

The transparent substrate 15 is a wiring board made of a thin transparent resin sheet such as an overhead projector (OHP) sheet, and as illustrated in FIG. 5, a plurality of LEDs 20 which are light emitting elements are mounted. The transparent substrate 15 is made of a colorless and transparent material such as polycarbonate, acrylic, or glass. The LED 20 is mounted with a light emitting surface facing upward. The LED 20 is preferably a full-color LED. In the example illustrated in FIG. 5, the LEDs 20 are arranged along four sides corresponding to the peripheral edge of the transparent substrate 15, and arranged so as to draw large and small squares in a central part of the transparent substrate 15 along the longitudinal direction. The LEDs 20 can be arranged at freely selected positions on the transparent substrate 15 and arranged in accordance with the content to be displayed by the light emitted from the LEDs 20. The transparent substrate 15 mounted with the LED 20 constitutes a light emitting part.

The LED control board (light emission control board) 14 is a control board that drives the plurality of LEDs 20 mounted on the transparent substrate 15. The LED control board 14 is divided into a plurality of parts, and in the example illustrated in FIG. 5, the LED control board 14 is disposed on the peripheral edge of the transparent substrate 15. Note that the placement position of the LED control board 14 is not limited to the peripheral edge of the transparent substrate 15. The LED control board 14 is electrically connected to the transparent substrate 15 to drive the plurality of LEDs 20.

The bottom base 16 is a casing on the rear surface (rear-side surface) of the display device 1 and accommodates on the inside the top panel 10, the two clear plates 13, the transparent substrate 15, the LED control board 14, and the like. As illustrated in FIG. 6, on the front surface (inner surface) of the bottom base 16, a mirror part (second mirror part) 19 is formed (dotted part in FIG. 6) by mirror deposition on the entire surface except for a peripheral edge to be fitted with the frame part 11. The mirror part 19 and the half mirror part 18 formed on the rear surface of the top panel 10 constitute a combination mirror. Note that the mirror part 19 may be formed by a method other than vapor deposition, such as attaching a mirror film.

The clear plate 13 is a transparent resin member filling a gap between the transparent substrate 15 and the top panel 10 and between the transparent substrate 15 and the bottom base 16. The clear plate 13 is made of a colorless and transparent material such as polycarbonate, acrylic, or glass. As illustrated in FIG. 7, the clear plate 13 is disposed on each of the light launching side and the rear surface side of the transparent substrate 15. By disposing the clear plate 13 on each side of the transparent substrate 15, an appropriate interval is maintained between the LED 20 and the half mirror part 18 and between the LED 20 and the mirror part 19. When the display device 1 is viewed from an oblique direction, the wider the interval, the wider the interval between the real image and the virtual image of the LED, which will be described later, and the interval between the virtual image and the virtual image.

Returning to FIG. 2, as illustrated in the figure, the lower clear plate 13, the transparent substrate 15 on which the LED control board 14 is disposed at the peripheral edge, the upper clear plate 13, and the top panel 10 are disposed in this order on the bottom base 16, and the frame part 11 is fitted to the bottom base 16 from above. After the fitting, the frame part 11 and the bottom base 16 are fixed using a screw or the like (not illustrated).

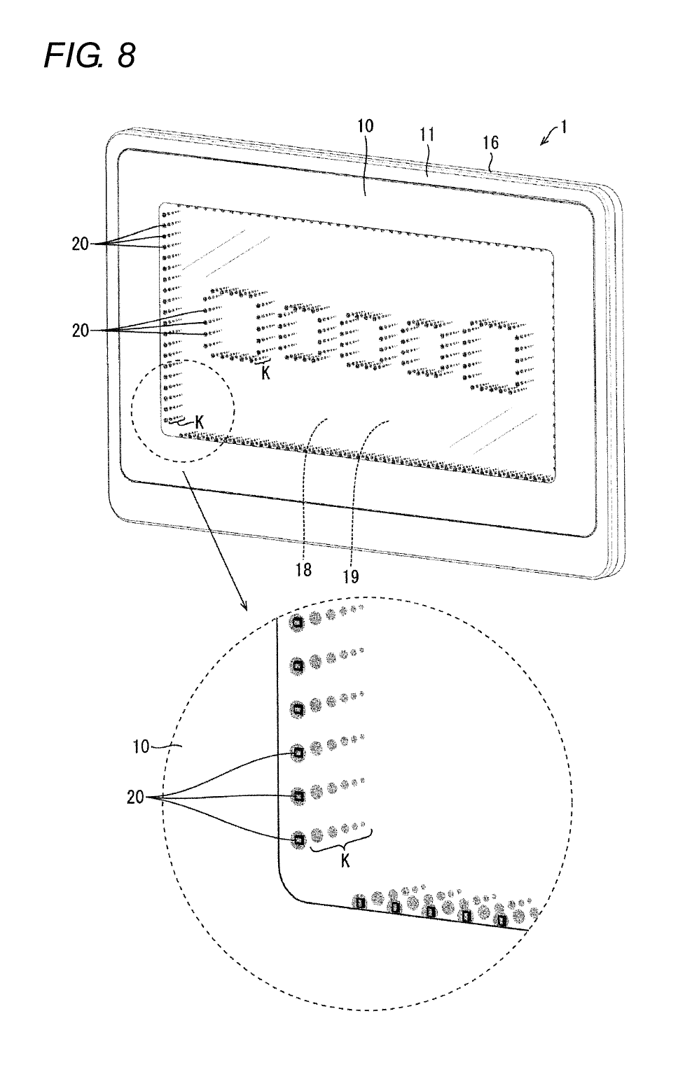

FIG. 8 is an explanatory view and a partially enlarged view illustrating a state in which the display device 1 is performing a light emission display. In the display device 1 configured as described above, when the LED 20 is turned on, light is emitted from the LED 20. A user can see a real image of the light emitted from the lighted LED 20 and a virtual image of the light emitted from the lighted LED 20 via the half mirror part 18 having the light transmission function. A part of the light emitted from the LED 20 travels by being repeatedly reflected between the half mirror part 18 and the mirror part 19 (cf. FIG. 7).

In the example illustrated in the embodiment, since the half mirror part 18 and the mirror part 19 are disposed in parallel, the light reflected on the mirror part 19 is superimposed on the LED 20 in the state of the user facing and viewing the display device 1 (as viewed parallelly to the mirror part 19). However, in the state of the user obliquely viewing the display device 1 (as viewed non-parallelly to the mirror part 19), the light is seen as if being located behind (depth direction) the LEDs 20 (cf. reference symbol K in FIG. 8).

That is, as viewed from the user, as illustrated in FIG. 8, by action of the combination mirror formed of the front half mirror part 18 and the rear side mirror part 19, the LED is seen as if a plurality of LEDs are arranged continuously rearward (in the depth direction) from the arrangement position of the LED 20. In other words, the virtual image of the LED 20 is seen as if continuing or intermittently continuing in the depth direction (rearward).

This can cause the user to have illusion that the display device 1 is spreading towards the rear and feel the depth of the display device 1. In the configuration in which the half mirror part 18 and the mirror part 19 are disposed in parallel, the smaller the angle formed between the eye of the user and the mirror part 19 in a plan view (the more obliquely viewed), the larger the number of lights continuing rearward from the LED 20 becomes and the stronger impression of the sense of depth is provided.

Moreover, in the above configuration, since the LED 20 is arranged on the transparent substrate 15, it is possible to dispose the LED 20 at a freely selected position without hindering the action of the combination mirror. In the example of FIG. 8, the LEDs 20 are arranged in the peripheral edge of the display area along the black printed part 17, and arranged so as to draw five squares in the central part of the display area. As thus described, the use of the transparent substrate 15 makes it possible to perform an emission light display of a freely selected symbol and achieve a light emission display having the sense of depth with high degree of freedom while maintaining the thinness of the display device 1.

Further, the plurality of LEDs 20 arranged in this manner are caused to sequentially emit light around a predetermined direction, sequentially change an emission color around a predetermined direction, or blink and light a part of the LEDs 20, thereby enabling a light emission display with motion.

### Second Embodiment

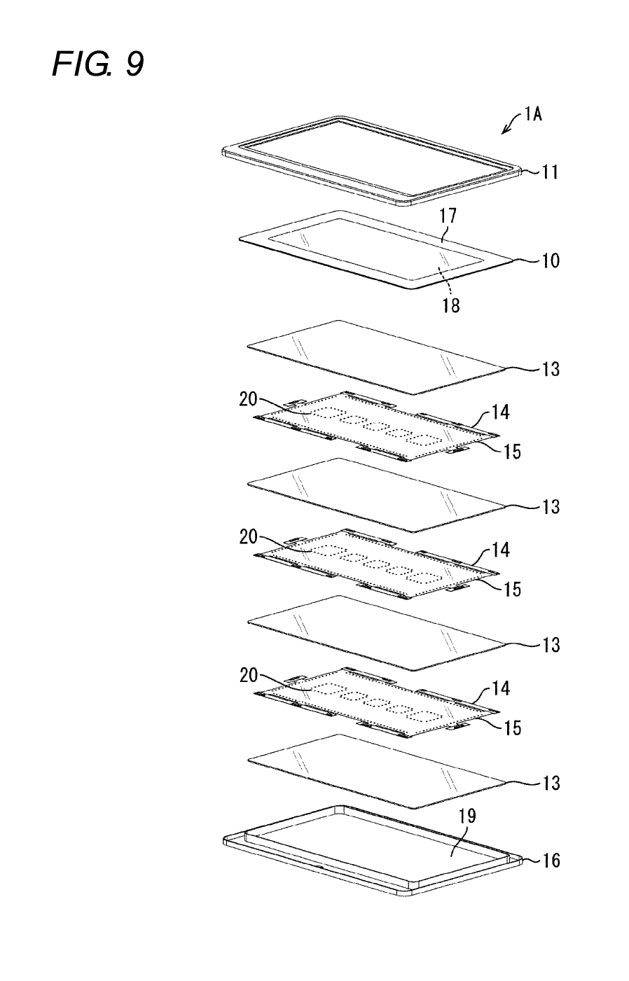

Hereinafter, another embodiment in one aspect of the present invention will be exemplified with reference to FIGS. 9 to 12. For convenience of description, members having the same functions as the members described in the above embodiment are denoted by the same reference numerals, and the description thereof is not repeated.

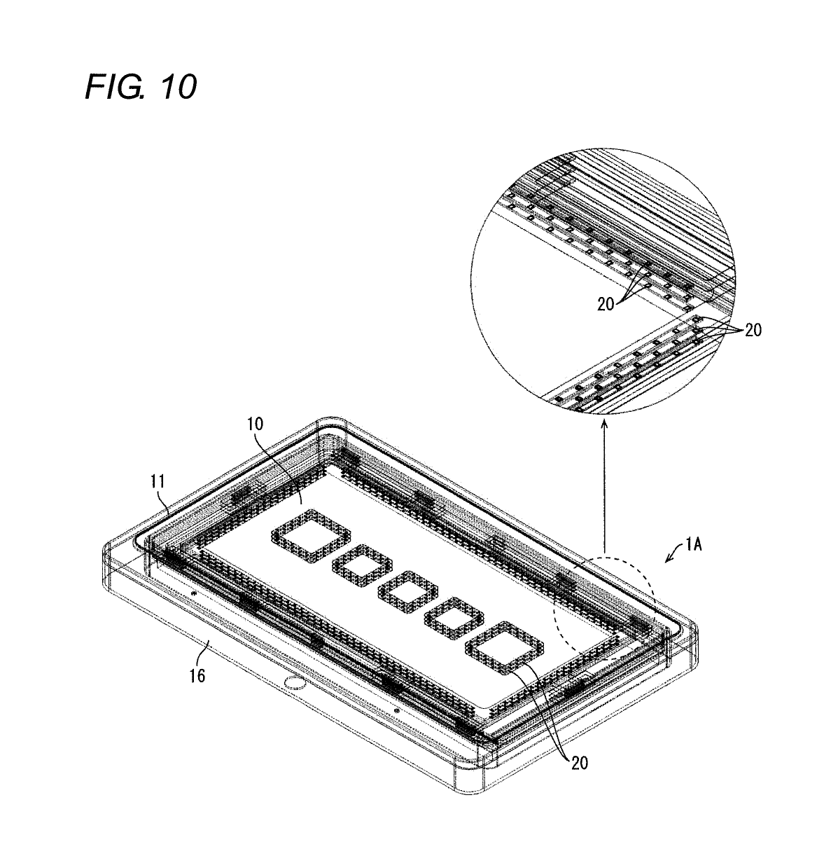

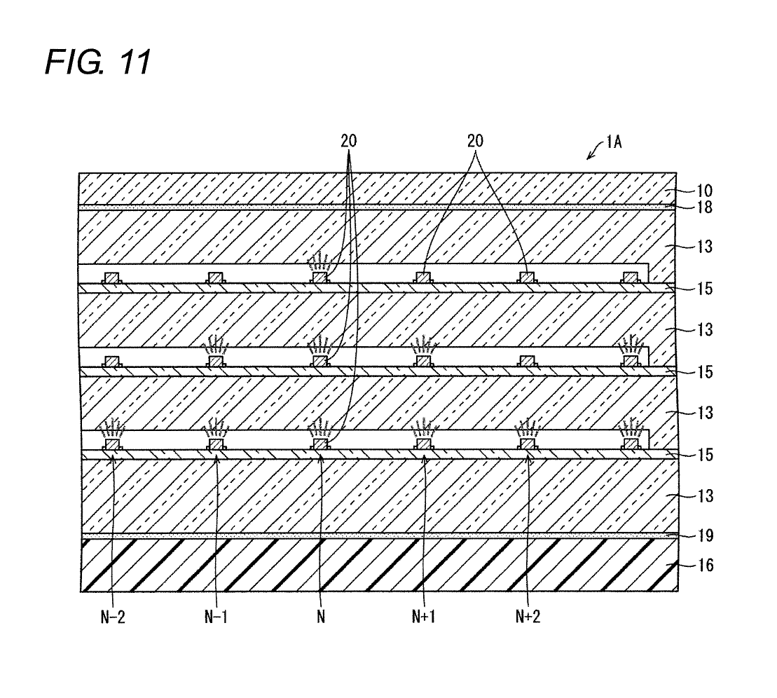

FIG. 9 is an exploded perspective view of the display device 1A according to the embodiment. FIG. 10 is a transmission perspective view and a partially enlarged view of the display device 1A. FIG. 11 is a vertical sectional view of a main part of the display device 1A.

As exemplified in FIGS. 9 to 11, the display device 1A includes three transparent substrates 15, each having the LED control board 14 disposed on the peripheral edge as the light emitting part, and four clear plates 13. Each of the three transparent substrates 15 is laminated with the clear plate 13 interposed therebetween, and the clear plate 13 is also disposed on each of the transparent substrates 15 in the uppermost and lowermost layers.

In the display device 1A configured as described above, since a plurality (three in the example) of LEDs 20 are actually arranged continuously toward the rear of the display device 1A, light rows (virtual images) which are continuously viewed rearward are large in number and have high light intensity and luminance as compared to the display device 1 of the first embodiment.

In addition, by forming the layer in which the LED 20 is disposed in multiple layers, it is possible to achieve a complicated light emission display that cannot be achieved in one layer. For example, three LEDs 20 arranged in the depth direction are taken as one set, and as illustrated in FIG. 11, when attention is paid to five successive sets of the LEDs 20, the three LEDs 20 in the uppermost layer, the intermediate layer, and the lowermost layer are lit in set N positioned at the center. Further, the LEDs 20 in the intermediate layer and the lowermost layer are lit in each of a set N−1 and a set N+1 being both sides of the set N. Moreover, the LEDs 20 in only the lowermost layer are lit in each of a set N−2 and a set N+2 being outside the set N−1 and the set N+1. By lighting in such a pattern, when a group of light rearward is viewed as band-like light, the side in front of the light band can be shown as if drawing a zigzag line.

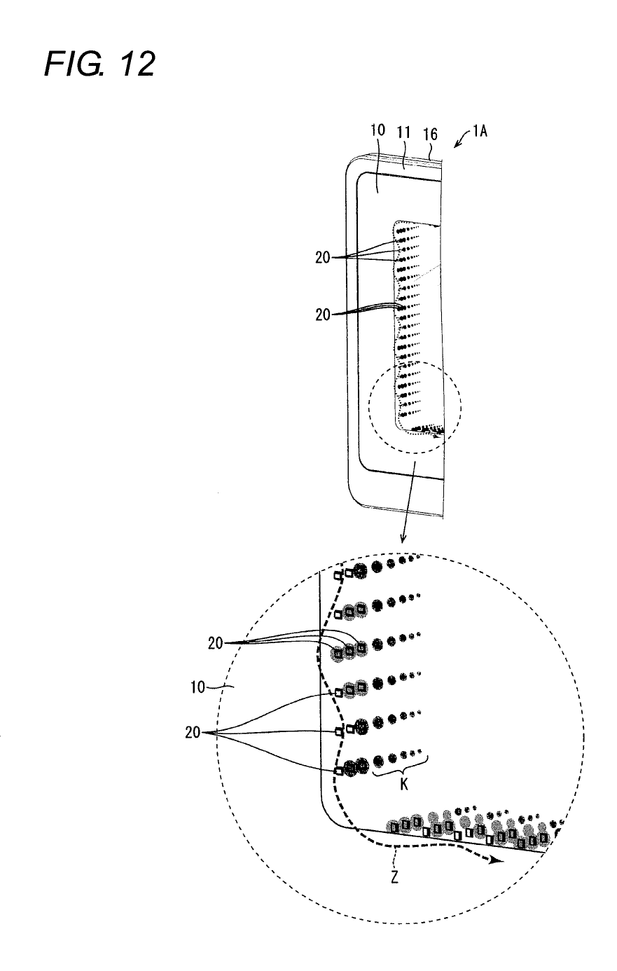

Further, as illustrated in FIG. 12, by keeping the lighting pattern illustrated in FIG. 11 and sequentially emitting a plurality of sets of LEDs 20 around a predetermined direction or sequentially changing an emission color around a predetermined direction, a light emission display with motion can be performed in which the band of light is seen as if advancing in a predetermined direction while drawing a zigzag line (arrow Z). FIG. 12 is an explanatory view and a partially enlarged view illustrating a state in which the display device 1A is performing a light emission display. In FIG. 12, lights by real images and virtual images are indicated by halftone circles.

Although the configuration has been exemplified in the embodiment where the three transparent substrates 15 mounted with the LEDs 20 are laminated, the number of transparent substrates 15 to be laminated may be two or four or more. By providing a plurality of transparent substrates 15, the degree of freedom that can be expressed by light emission display is higher than that of the display device 1 including only one transparent substrate 15, and a more entertaining and more impactful display can be achieved. With the transparent substrate 15 in use, even when a plurality of transparent substrates are laminated, the thinness of the display device 1A is not hindered and the thin form can be maintained.

### Third Embodiment

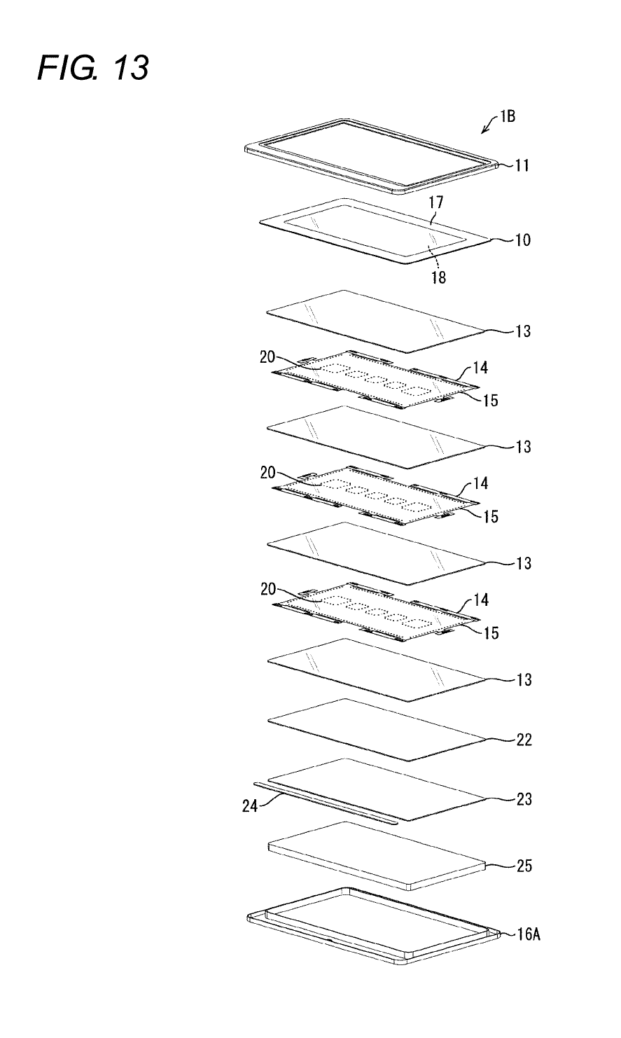

Hereinafter, another embodiment in one aspect of the present invention will be exemplified based on FIG. 13. For convenience of description, members having the same functions as the members described in the above embodiment are denoted by the same reference numerals, and the description thereof is not repeated.

FIG. 13 is an exploded perspective view of the display device 1B according to the embodiment. As illustrated in FIG. 13, the display device 1B includes a bottom base 16A in which the mirror part 19 is not formed on the front surface (inner surface), instead of the bottom base 16 in the display device 1A of the second embodiment. Further, the display device 1B includes, between a clear plate 13 in the lowermost layer and the bottom base 16A, a half mirror plate (second mirror part) 22, a transparent backlight 23, a backlight substrate 24, and a liquid crystal unit 25.

The display device 1B includes the half mirror plate 22 instead of the mirror part 19, and the half mirror plate 22 and the half mirror part 18 constitutes a combination mirror. The half mirror plate 22 is obtained by performing half mirror deposition on a transparent resin member similar to the clear plate 13, or by attaching a half mirror film.

The liquid crystal unit 25 is an image display part for displaying various images. In the embodiment, an LCD using a liquid crystal is exemplified as the image display part, but the display panel is not limited to the LCD but may be a thin type image display device based on image data such as one using an organic electroluminescence (EL).

The transparent backlight 23 illuminates the rear surface side of the half mirror plate 22, and the backlight substrate 24 is disposed on one side. The backlight substrate 24 has a light source for supplying the transparent backlight 23, and controls the turning on/off of the transparent backlight 23. The transparent backlight 23 and the backlight substrate 24 constitute a light source part for increasing the transmitted light of the half mirror plate 22.

In the display device 1B configured as described above, the light emission display by the LED 20 mounted on the transparent substrate 15 and the image display by the liquid crystal unit 25 are selectively performed. In a light emission display mode for performing the light emission display by the LED 20, the LED control board 14 controls the LED 20 to perform the light emission display. In an image display mode for performing the image display by the liquid crystal unit 25, the liquid crystal unit 25 displays an image based on image data by a control device provided in the liquid crystal unit 25. Note that the image data may be previously stored in a memory of the liquid crystal unit 25, or acquired from the outside of the liquid crystal unit 25 via a communication network.

In the image display mode, the transparent backlight 23 is turned on together with the liquid crystal unit 25. By turning on the transparent backlight 23, the image displayed on the liquid crystal unit 25 can be visually recognized in a favorable manner from the top panel 10 side even when the image passes through two half mirrors such as the half mirror part 18 and the half mirror plate 22.

In addition, in a case where sufficient transparent light can be obtained even when the light passes through the two half mirrors, such as a case where the amount of light of the backlight included in the liquid crystal unit 25 is sufficiently strong, and a case where the display panel of spontaneous light such as organic EL is used and the light amount is sufficiently strong, the transparent backlight 23 and the backlight substrate 24 can be omitted.

Although the combination of the display device 1A of the second embodiment and the liquid crystal unit 25 has been exemplified in the embodiment, needless to say, a combination of the display device 1 of the first embodiment and the liquid crystal unit 25 may be used.

### Fourth Embodiment

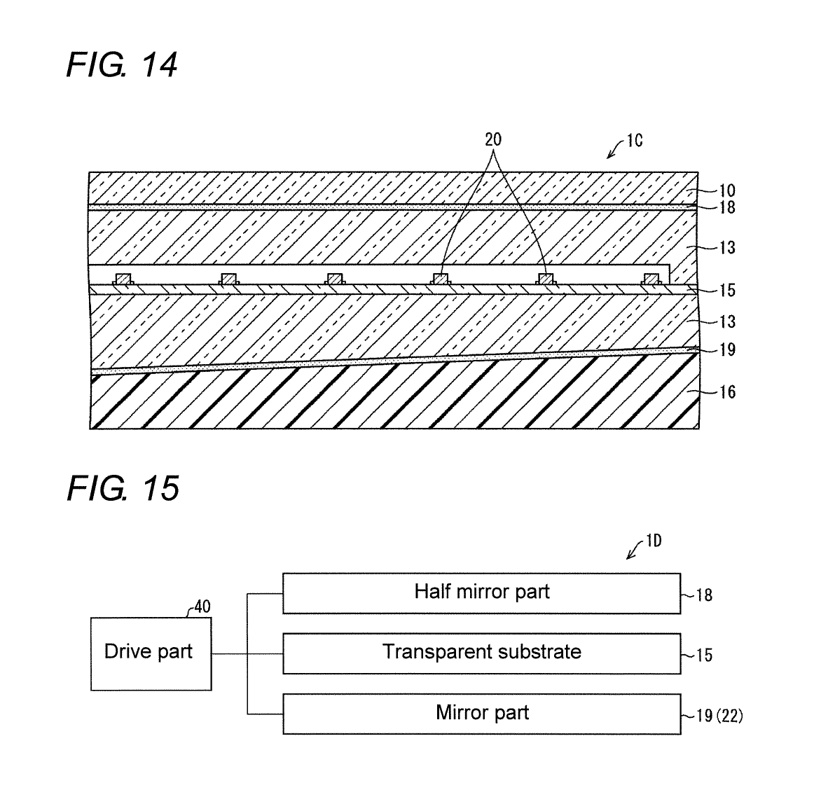

Hereinafter, another embodiment in one aspect of the present invention will be exemplified based on FIG. 14. For convenience of description, members having the same functions as the members described in the above embodiment are denoted by the same reference numerals, and the description thereof is not repeated.

FIG. 14 is a vertical sectional view of a main part of a display device 1C according to the embodiment. As illustrated in FIG. 14, in the display device 1C, the half mirror part 18 and the mirror part 19 are disposed with an angle formed therebetween and in a non-parallel state. As a result, even when the display device 1C is viewed from the front, a virtual image of light continuing toward the rear can be shown.

Although FIG. 14 exemplifies the configuration having one transparent substrate 15, the embodiment may be adopted for a configuration having a plurality of transparent substrates 15 or a configuration using the half mirror plate 22 provided with the liquid crystal unit 25.

### Fifth Embodiment

Hereinafter, another embodiment in one aspect of the present invention will be exemplified based on FIG. 15. For convenience of description, members having the same functions as the members described in the above embodiment are denoted by the same reference numerals, and the description thereof is not repeated.

FIG. 15 is a block diagram of a main part of a display device 1D according to the embodiment. As illustrated in FIG. 15, the display device 1D includes a drive part 40 that makes movable a half mirror part 18 constituting a first mirror part, at least one transparent substrate 15 constituting a light emitting part, and a mirror part 19 (or a half mirror plate 22) constituting a second mirror part. For example, the drive part 40 moves the half mirror part 18, the mirror part 19 (or the half mirror plate 22), or the transparent substrate 15 by, for example, moving a part thereof in a wavy manner or partially pushing up a part thereof.

As a result, it is possible to cause the real image of the LED 20 and the virtual image thereof to move. In the configuration of moving an image in a wavy manner, the half mirror part 18 and the mirror part 19 may be formed by vapor deposition, sticking a film, or the like on a flexible transparent member.

### § 3 MODIFICATIONS

Although the embodiments of the present invention have been described in detail above, the above description is merely an example of the present invention in all respects. It goes without saying that various improvements and modifications can be made without departing from the scope of the present invention. For example, the following modifications are possible. Hereinafter, the same reference numerals are used for the same constituent elements as those in the above embodiment, and the same explanation as in the above embodiment is omitted as appropriate. The following modified examples can be appropriately combined as appropriate.

For example, although the configuration has been exemplified in the above second and third embodiments where the plurality of LEDs 20 are arranged in a line in the depth direction in a plan view, the configuration is not limited to the configuration of arrangement in a line. For example, when the state in which the plurality of transparent substrates 15 are laminated is viewed in a plan view, the arrangement positions of the LEDs 20 mounted on each transparent substrate 15 may be deviated, and a portion not overlapping may be included. Further, the plurality of LEDs 20 arranged in the depth direction may be arranged with an inclination with respect to the depth direction.

Although the configuration has been formed in the first to third embodiments where the LED 20 is mounted on the transparent substrate 15 with the light emitting surface facing upward, the present invention is not limited to the configuration in which the light emitting surface faces directly upward. The LED 20 may be mounted in a state in which the emission direction is inclined with respect to the surface of the transparent substrate 15 as far as the inclination is in a range where light can be emitted upward (the surface side of each of the display devices 1, 1A, 1B).

Further, in the first to sixth embodiments, the configuration having the flat surfaces as the half mirror part 18, the mirror part 19, the half mirror part 18 and the half mirror plate 22 has been exemplified. However, it is also possible to make the size and the position of the virtual image of light appear random (irregular) by bending the mirror part 19 or the half mirror plate 22 disposed in the back, and for example, the virtual image can be shown as a star in the space.

The present invention is not restricted to each of the embodiments described above, but can be subjected to a variety of changes in the scope shown in the claims. An embodiment obtained by appropriately combining technical units disclosed respectively in different embodiments is also included in a technical scope of the present invention.

1. A display device, comprising:
a light emitting part having at least one transparent substrate, on a front surface of which a plurality of light emitting elements are mounted;
a light emission control board configured to control light emission of the plurality of light emitting elements;
a first mirror part disposed on a light launching side of the light emitting part and having a light reflection function and a light transmission function; and
a second mirror part disposed on a rear surface side of the light emitting part and having at least the light reflecting function out of the light reflecting function and the light transmission function.

2. The display device according to claim 1, wherein
the light emitting part includes a plurality of the transparent substrates, and
the plurality of transparent substrates are laminated.

3. The display device according to claim 2, wherein at least a part of the plurality of light emitting elements mounted on each of the plurality of transparent substrates overlaps in a plan view.

4. The display device according to claim 1, wherein the first mirror part and the second mirror part are disposed in a non-parallel state.

5. The display device according to claim 1, wherein
the second mirror part has the light reflection function and the light transmission function, and
an image display part configured to display an image based on image data is further provided on a rear surface side of the second mirror part.

6. The display device according to claim 5, further comprising, between the light emitting part and the image display part:
a light source part configured to increase light that passes through the second mirror part.

7. A game machine comprising
the display device according to claim 1.

8. The display device according to claim 2, wherein the first mirror part and the second mirror part are disposed in a non-parallel state.

9. The display device according to claim 3, wherein the first mirror part and the second mirror part are disposed in a non-parallel state.

10. The display device according to claim 2, wherein
the second mirror part has the light reflection function and the light transmission function, and
an image display part configured to display an image based on image data is further provided on a rear surface side of the second mirror part.

11. The display device according to claim 3, wherein
the second mirror part has the light reflection function and the light transmission function, and
an image display part configured to display an image based on image data is further provided on a rear surface side of the second mirror part.

12. The display device according to claim 4, wherein
the second mirror part has the light reflection function and the light transmission function, and
an image display part configured to display an image based on image data is further provided on a rear surface side of the second mirror part.

13. A game machine comprising
the display device according to claim 2.

14. A game machine comprising
the display device according to claim 3.

15. A game machine comprising
the display device according to claim 4.

16. A game machine comprising
the display device according to claim 5.

17. A game machine comprising
the display device according to claim 6.
